(19) United States
(12) Patent Application Publication
(10) Pub. No.: US 2010/0244030 A1
(43) Pub. Date: Sep. 30, 2010

(54) PHOTOELECTRIC CONVERSION ELEMENT AND IMAGING DEVICE

(75) Inventors: Daigo SAWAKI, Kanagawa (JP); Tetsuro MITSUI, Kanagawa (JP)

Correspondence Address: SUGHRUE-265550, 2100 PENNSYLVANIA AVE. NW, WASHINGTON, DC, 20037-3213, US

(73) Assignee: FUJIFILM CORPORATION, Tokyo (JP)

(21) Appl. No.: 12/749,917

(22) Filed: Mar. 30, 2010

(30) Foreign Application Priority Data
Mar. 30, 2009 (JP) 2009-083771

(51) Int. Cl. H01L 31/0376

(52) U.S. Cl. 257/53; 257/E31.047

(57) ABSTRACT

A photoelectric conversion element includes, in the following order: a substrate; a lower electrode; a photoelectric conversion layer; and an upper electrode comprising a transparent electrode material, the photoelectric conversion element further includes a stress relieving layer provided between the upper electrode and the photoelectric conversion layer, and the stress relieving layer includes a crystal layer capable of relieving a stress of the transparent electrode material.

### CROSS-REFERENCE TO RELATED APPLICATIONS

This application claims the benefit of Japanese Patent Application JP 2009-083771, filed Mar. 30, 2009, the entire content of which is hereby incorporated by reference, the same as if set forth at length.

### FIELD OF THE INVENTION

The present invention relates to a photoelectric conversion element and an imaging device.

### BACKGROUND OF THE INVENTION

At present, a photoelectric conversion element fabricated by providing a photoelectric conversion layer between a pair of electrodes each composed of an electrically conductive thin layer is known. The photoelectric conversion element is a device of producing an electric charge in the photoelectric conversion layer according to light incident from the side of a transparent electrode having light transmitting property out of the pair of electrodes and reading the produced electric charge as a signal charge from the electrode. As regards such a photoelectric conversion element, for example, those described in JP-A-11-87068 (the term “JP-A” as used herein means an “unexamined published Japanese patent application”) and JP-A-2002-359086 are known.

One of important optical properties of the photoelectric conversion element is high-speed responsivity. Envisaging a photoelectric conversion element having a configuration where the upper electrode is an ITO thin layer and an electron is trapped by the lower electrode, the resistance of the ITO thin layer must be reduced as a way to enhance the high-speed responsivity.

### SUMMARY OF THE INVENTION

Meanwhile, in a photoelectric conversion element having the above-described configuration, the thickness of the ITO layer needs to be made small for reducing the resistance of the ITO layer, but in this case, it is feared that due to internal stress of the ITO layer, adherence between the ITO layer and the photoelectric conversion layer is deteriorated or distortion is produced in the photoelectric conversion layer, resulting in reduction of the photoelectric conversion efficiency.

In an attempt to suppress the reduction of photoelectric conversion efficiency, for example, JP-A-11-87068 describes an organic EL device, where as a result of studies to modify the deposition property, adherence or layer physical properties at the interface between an electrode composed of an ITO layer, which is a hole injection electrode, and an organic layer, it has been found that deterioration at the interface is reduced by specifying the alignment plane of the ITO layer to a predetermined orientation. However, the internal stress attributable to a material constituting the electrode such as ITO layer is not relieved.

JP-A-2002-359086 relates to an organic electroluminescence element having an organic light-emitting layer between a transparent electron-injection electrode on the device surface side and a hole injection electrode on the substrate side and collecting light from the device surface side. In this organic electroluminescence element, a porphyrin-based compound is inserted as a buffer layer between the electron injection electrode and the organic light-emitting layer so as to enhance the luminescence efficiency. However, an internal stress attributable to a material constituting the electrode such as ITO layer is not relieved.

The present invention has been made under these circumstances and provides a photoelectric conversion element capable of enhancing the photoelectric conversion efficiency by relieving an internal stress produced due to a material constituting an electrode, and an imaging device.

The photoelectric conversion element of the present invention is a photoelectric conversion element comprising a substrate having thereon, in order, a lower electrode, a photoelectric conversion layer, and an upper electrode containing a transparent electrode material, wherein

a stress relieving layer comprising a crystal layer capable of relieving a stress of the transparent electrode material is provided between the upper electrode and the photoelectric conversion layer.

Also, the imaging device of the present invention is equipped with the above-described photoelectric conversion element and comprises:

a semiconductor substrate having stacked thereabove the photoelectric conversion layer,

an electric charge accumulating part formed inside of the semiconductor substrate for accumulating an electric charge generated in the photoelectric conversion layer, and

a connection part for transmitting an electric charge of the photoelectric conversion layer to the electric charge accumulating part.

According to the present invention, a photoelectric conversion element capable of enhancing the photoelectric conversion efficiency by relieving an internal stress produced due to a material constituting an electrode, and an imaging device can be provided.

### BRIEF DESCRIPTION OF THE DRAWINGS

FIG. 1 is a cross-sectional schematic view showing one configuration example of the photoelectric conversion element.

FIG. 2 is a cross-sectional schematic view showing another configuration example of the photoelectric conversion element.

FIGS. 3A and 3B are views schematically showing a force acting on a thin layer deposited on a substrate.

FIG. 4 is a configuration example of the apparatus for measuring the amount of warpage of a substrate.

FIG. 5 is a cross-sectional schematic view of one pixel portion of an imaging device.

FIG. 6 is a cross-sectional schematic view of one pixel portion of an imaging device in another configuration example.

FIG. 7 is a cross-sectional schematic view of one pixel portion of an imaging device in still another configuration example.

### DESCRIPTION OF REFERENCE NUMERALS AND SIGNS

11 Electrically conductive thin layer (lower electrode)
12 Photoelectric conversion layer
15 Transparent electrode (upper electrode)
16 Crystal layer
S Substrate

### DETAILED DESCRIPTION OF THE INVENTION

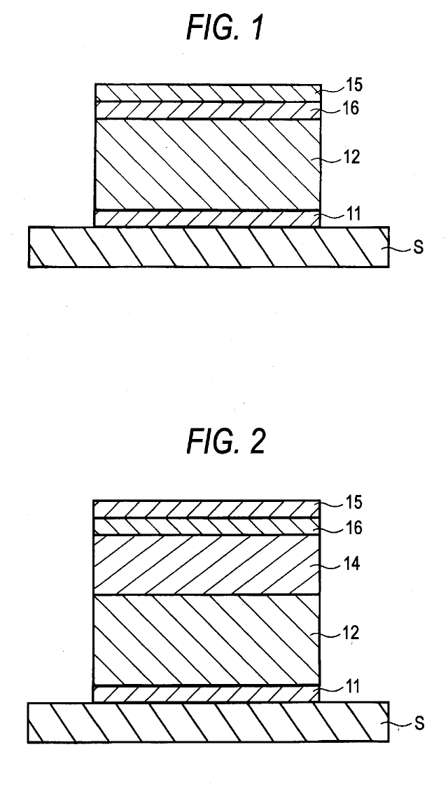

FIG. 1 is a cross-sectional schematic view showing one configuration example of the photoelectric conversion element, and FIG. 2 is a cross-sectional schematic view showing another configuration example of the photoelectric conversion element.

The photoelectric conversion element shown in FIG. 1 has a configuration where a substrate S, an electrically conductive thin layer (hereinafter referred to as a “lower electrode”) 11 functioning as a lower electrode formed on the substrate S, a photoelectric conversion layer 12 formed on the lower electrode 11, and a transparent electrode (hereinafter referred to as an “upper electrode”) 15 functioning as an upper electrode are stacked in this order. Incidentally, in the photoelectric conversion layer, a layer other than the lower electrode 11, the photoelectric conversion layer 12 and the upper electrode 15 may be provided.

In the photoelectric conversion element shown in FIG. 1, a stress relieving layer 16 composed of a crystal layer capable of relieving a stress of a transparent electrode material of the upper electrode 15 is provided between the upper electrode 15 and the photoelectric conversion layer 12.

The photoelectric conversion element shown in FIG. 2 comprises a substrate S, a lower electrode (pixel electrode) 11 formed on the substrate S, a photoelectric conversion layer 12 formed on the lower electrode 11, a non-crystal layer 14 formed on the photoelectric conversion layer 12, a crystal layer 16 formed on the non-crystal layer 14, and an upper electrode 15 formed on the crystal layer 16. In this photoelectric conversion element, the non-crystal layer 14 and the crystal layer 16 function as a charge blocking layer for inhibiting injection of a carrier into the photoelectric conversion layer from the upper electrode 15. Incidentally, the photoelectric conversion element is not limited to the configuration where the crystal layer 16 is provided between the upper electrode 15 and the charge blocking layer, and may be configured such that the crystal layer 16 constitutes a part of the charge blocking layer. In the case where the crystal layer 16 is formed as a part of the charge blocking layer, it is also possible to form the crystal layer 16 at the interface of the charge blocking layer being in contact with the upper electrode 15 and form the other portion by using a noncrystalline material such as amorphous layer. In the following, a hole blocking layer and an electron blocking layer are sometimes collectively called a charge blocking layer.

Incidentally, unless otherwise indicated, the lower electrode 11, the photoelectric conversion layer 12, the crystal layer 16 and the upper electrode 15 in the photoelectric conversion element of FIG. 2 can have the same configuration as that in the photoelectric conversion element of FIG. 1.

The photoelectric conversion element shown in FIGS. 1 and 2 are designed to allow light to enter from above the upper electrode 15 that is transparent. Also, in the photoelectric conversion element, a bias voltage is applied between the lower electrode 11 and the upper electrode 15 so that, with respect to the electric charge (a hole and an electron) generated in the photoelectric conversion layer 12, a hole can be transferred to the upper electrode 15 and an electron can be transferred to the lower electrode 11. That is, the upper electrode 15 works as a hole trapping electrode, and the lower electrode 11 works as an electron trapping electrode.

Examples of the electrically conductive material which can be used for the upper electrode 15 and the lower electrode 11 include a metal, an alloy, a metal oxide, an electrically conductive compound and a mixture thereof. The metal material includes an arbitrary combination selected from Li, Na, Mg, K, Ca, Rb, Sr, Cs, Ba, Fr, Ra, Sc, Ti, Y, Zr, Hf, V, Nb, Ta, Cr, Mo, W, Mn, Tc, Re, Fe, Ru, Os, Co, Rh, Ir, Ni, Pd, Pt, Cu, Ag, Au, Zn, Cd, Al, Ga, In, Tl, Si, Ge, Sn, Pb, P, As, Sb, Bi, Se, Te, Po, Br, I, At, B, C, N, F, O, S, and N. Above all, Al, Pt, W, Au, Ag, Ta, Cu, Cr, Mo, Ti, Ni, Pd and Zn are preferred.

The lower electrode 15 collects and traps an electron from an electron-transporting photoelectric conversion layer or an electron transport layer and therefore, the material is selected by taking into consideration the adherence to an adjacent layer such as electron-transporting photoelectric conversion layer or electron transport layer, the electron affinity, the ionization potential, the stability and the like.

The upper electrode 11 collects and traps an electron from a hole-transporting photoelectric conversion layer or a hole transport layer and therefore, the material is selected by taking into consideration the adherence to an adjacent layer such as hole-transporting photoelectric conversion layer or hole transport layer, the electron affinity, the ionization potential, the stability and the like. Specific examples of these materials include an electrically conductive metal oxide such as tin oxide, zinc oxide, indium oxide and indium tin oxide (ITO), a metal such as gold, silver, chromium and nickel, a mixture or stack of such a metal and such an electrically conductive metal oxide, an inorganic electrically conductive substance such as copper iodide and copper sulfide, an organic electrically conductive material such as polyaniline, polythiophene and polypyrrole, a silicon compound, and a stack thereof with ITO. Among these, an electrically conductive metal oxide is preferred, and ITO, ZnO and InO are more preferred in view of productivity, high electrical conductivity, transparency and the like.

Light needs to be incident on the photoelectric conversion layer 12 and therefore, the upper electrode 15 is composed of a transparent electrically conductive material. The transparent electrically conductive material is preferably a material having a transmittance of about 80% or more in the visible light region at a wavelength of from about 420 nm to about 660 nm.

For the production of the electrode, various methods may be used according to the material, but, for example, in the case of ITO, the layer is deposited by a method such as electron beam method, sputtering method, resistance heating deposition method, chemical reaction method (e.g., sol-gel method) or coating of a dispersion of indium tin oxide. In the case of ITO, an UV-ozone treatment, a plasma treatment or the like can be applied.

As for the conditions when depositing a transparent electrically conductive layer suitable for the upper electrode 15, the silicon substrate temperature during layer deposition is preferably 500° C. or less, more preferably 300° C. or less, still more preferably 200° C. or less, yet still more preferably 150° C. or less. A gas may be introduced during layer deposition and although the gas species is fundamentally not limited, Ar, He, oxygen, nitrogen or the like can be used. A mixed gas of these gases may be also used. In particular, when the material is an oxide, an oxygen defect often enters the layer and therefore, oxygen is preferably used.

The lower electrode 11 is sufficient if it is an electrically conductive material, and need not be transparent. However, in the case where light is required to be transmitted also to the substrate S side below the lower electrode 11, the lower electrode 11 is also preferably composed of a transparent electrode material. As for the transparent electrode material of the lower electrode 11, use of ITO is preferred similarly to the upper electrode 14.

The photoelectric conversion layer 12 is fabricated to contain an organic material having a photoelectric conversion function. As for the organic material, various organic semiconductor materials used, for example, as a light-sensitive material in electrophotography can be used. Above all, in view of, for example, high photoelectric conversion performance, excellent color separation at the light dispersion, high resistance to light irradiation over a long time and easiness of vacuum deposition, a material containing a quinacridone skeleton or an organic material containing a phthalocyanine skeleton is preferred.

In the case of using quinacridone as the photoelectric conversion layer 12, light in the green wavelength region can be absorbed by the photoelectric conversion layer 12, and an electric charge according to light absorbed can be generated.

For the photoelectric conversion layer 12, zinc phthalocyanine can be used. In this case, light in the red wavelength region can be absorbed by the photoelectric conversion layer 12, and an electric charge according to light absorbed can be generated.

The organic material constituting the photoelectric conversion layer 12 preferably contains at least either one of a p-type organic semiconductor and an n-type organic semiconductor. In particular, any one of a quinacridone derivative, a naphthalene derivative, an anthracene derivative, a phenanthrene derivative, a tetracene derivative, a pyrene derivative, a perylene derivative and a fluoranthene derivative may be preferably used for each of the p-type organic semiconductor and the n-type semiconductor.

The p-type organic semiconductor (compound) is a donor-type organic semiconductor (compound) and indicates an organic compound having a property of readily donating an electron, mainly typified by a hole-transporting organic compound. More specifically, this is an organic compound having a smaller ionization potential when two organic materials are used in contact. Accordingly, the donor-type organic compound may be any organic compound as long as it is an organic compound having an electron donating property. Examples of the compound which can be used include a triarylamine compound, a benzidine compound, a pyrazoline compound, a styrylamine compound, a hydrazone compound, a triphenylmethane compound, a carbazole compound, a polysilane compound, a thiophene compound, a phthalocyanine compound, a cyanine compound, a merocyanine compound, an oxonol compound, a polyamine compound, an indole compound, a pyrrole compound, a pyrazole compound, a polyarylene compound, a fused aromatic carbocyclic compound (e.g., naphthalene derivative, anthracene derivative, phenanthrene derivative, tetracene derivative, pyrene derivative, perylene derivative, fluoranthene derivative), and a metal complex having a nitrogen-containing heterocyclic compound as a ligand. The donor-type organic semiconductor is not limited to these compounds and, as described above, any organic compound having an ionization potential smaller than that of the organic compound used as an n-type (acceptor) compound may be used as the donor-type organic semiconductor.

The n-type organic semiconductor (compound) is an acceptor-type organic semiconductor (compound) and indicates an organic compound having a property of readily accepting an electron, mainly typified by an electron-transporting organic compound. More specifically, this is an organic compound having a larger electron affinity when two organic compounds are used in contact. Accordingly, for the acceptor-type organic compound, any organic compound can be used as long as it is an organic compound having an electron accepting property. Examples thereof include a fused aromatic carbocyclic compound (e.g., naphthalene derivative, anthracene derivative, phenanthrene derivative, tetracene derivative, pyrene derivative, perylene derivative, fluoranthene derivative), a 5- to 7-membered heterocyclic compound containing a nitrogen atom, an oxygen atom or a sulfur atom (e.g., pyridine, pyrazine, pyrimidine, pyridazine, triazine, quinoline, quinoxaline, quinazoline, phthalazine, cinnoline, isoquinoline, pteridine, acridine, phenazine, phenanthroline, tetrazole, pyrazole, imidazole, thiazole, oxazole, indazole, benzimidazole, benzotriazole, benzoxazole, benzothiazole, carbazole, purine, triazolopyridazine, triazolopyrimidine, tetrazaindene, oxadiazole, imidazopyridine, pyralidine, pyrrolopyridine, thiadiazolopyridine, dibenzazepine, tribenzazepine), a polyarylene compound, a fluorene compound, a cyclopentadiene compound, a silyl compound, and a metal complex having a nitrogen-containing heterocyclic compound as a ligand. The acceptor-type organic semiconductor is not limited to these compounds and, as described above, any organic compound having an electron affinity larger than that of the organic compound used as the donor-type organic compound may be used as the acceptor-type organic semiconductor.

As for the n-type organic semiconductor, a fullerene or a fullerene derivative is preferably used.

The fullerene indicates fullerene C₆₀, fullerene C₇₀, fullerene C₇₆, fullerene C₇₈, fullerene C₈₀, fullerene C₈₂, fullerene C₈₄, fullerene C₉₀, fullerene C₉₆, fullerene C₂₄₀, fullerene C₅₄₀, a mixed fullerene or a fullerene nanotube, and the fullerene derivative indicates a compound obtained by adding a substituent to such a fullerene.

As for the p-type organic dye or n-type organic dye, any dye may be used, but preferred examples thereof include a cyanine dye, a styryl dye, a hemicyanine dye, a merocyanine dyes (including zero-methine merocyanine (simple merocyanine)), a trinuclear merocyanine dye, a tetranuclear merocyanine dye, a rhodacyanine dye, a complex cyanine dye, a complex merocyanine dye, an alopolar dye, an oxonol dye, a hemioxonol dye, a squarylium dye, a croconium dye, an azamethine dye, a coumarin dye, an arylidene dye, an anthraquinone dye, a triphenylmethane dye, an azo dye, an azomethine dye, a spiro compound, a metallocene dye, a fluorenone dye, a flugide dye, a perylene dye, a phenazine dye, a phenothiazine dye, a quinone dye, an indigo dye, a diphenylmethane dye, a polyene dye, an acridine dye, an acridinone dye, a diphenylamine dye, a quinacridone dye, a quinophthalone dye, a phenoxazine dye, a phthaloperylene dye, a porphyrin dye, a chlorophyll dye, a phthalocyanine dye, a metal complex dye, and a fused aromatic carboxylic dye (e.g., naphthalene derivative, anthracene derivative, phenanthrene derivative, tetracene derivative, pyrene derivative, perylene derivative, fluoranthene derivative).

The metal complex compound is described below. The metal complex compound is a metal complex having at least one ligand containing a nitrogen, oxygen or sulfur atom coordinated to a metal. The metal ion in the metal complex is not particularly limited but is preferably beryllium ion, magnesium ion, aluminum ion, gallium ion, zinc ion, indium ion or tin ion, more preferably beryllium ion, aluminum ion, gallium ion or zinc ion, still more preferably aluminum ion or zinc ion. As for the ligand contained in the metal complex, various ligands are known, but examples thereof include ligands described in H. Yersin, Photochemistry and Photophysics of Coordination Compounds, Springer-Verlag (1987), and Akio Yamamoto, Yuki Kinzoku Kagaku—Kiso to Oyo—(Organic Metal Chemistry—Basic and Application—), Shokabo (1982).

The ligand is preferably a nitrogen-containing heterocyclic ligand (preferably having a carbon number of 1 to 30, more preferably from 2 to 20, still more preferably from 3 to 15; which may be a monodentate ligand or a bidentate or greater ligand and is preferably a bidentate ligand, such as pyridine ligand, bipyridyl ligand, quinolinol ligand, hydroxyphenylazole ligand (e.g., hydroxyphenylbenzimidazole, hydroxyphenylbenzoxazole, hydroxyphenylimidazole)), an alkoxy ligand (preferably having a carbon number of 1 to 30, more preferably from 1 to 20, still more preferably from 1 to 10, such as methoxy, ethoxy, butoxy and 2-ethylhexyloxy), an aryloxy ligand (preferably having a carbon number of 6 to 30, more preferably from 6 to 20, still more preferably from 6 to 12, such as phenyloxy, 1-naphthyloxy, 2-naphthyloxy, 2,4,6-trimethylphenyloxy and 4-biphenyloxy), a heteroaryloxy ligand (preferably having a carbon number of 1 to 30, more preferably from 1 to 20, still more preferably from 1 to 12, such as pyridyloxy, pyrazyloxy, pyrimidyloxy and quinolyloxy), an alkylthio ligand (preferably having a carbon number of 1 to 30, more preferably from 1 to 20, still more preferably from 1 to 12, such as methylthio and ethylthio), an arylthio ligand (preferably having a carbon number of 6 to 30, more preferably from 6 to 20, still more preferably from 6 to 12, such as phenylthio), a heterocycle-substituted thio ligand (preferably having a carbon number of 1 to 30, more preferably from 1 to 20, still more preferably from 1 to 12, such as pyridylthio, 2-benzimizolylthio, 2-benzoxazolylthio and 2-benzothiazolylthio), or a siloxy ligand (preferably having a carbon number of 1 to 30, more preferably from 3 to 25, still more preferably from 6 to 20, such as triphenylsiloxy group, triethoxysiloxy group and triisopropylsiloxy group), more preferably a nitrogen-containing heterocyclic ligand, an aryloxy ligand, a heteroaryloxy group or a siloxy ligand, still more preferably a nitrogen-containing heterocyclic ligand, an aryloxy ligand or a siloxy ligand.

Also, the photoelectric conversion 12 may be fabricated to contain an amorphous layer composed of an amorphous material that is a noncrystalline structure.

The photoelectric conversion element shown in FIG. 2 may be fabricated to contain both an electron blocking layer and a hole blocking layer as the charge blocking layer. That is, the photoelectric conversion element may have a configuration where a charge blocking layer is provided also between the photoelectric conversion layer 12 and the lower electrode 11 and according to the direction in which a voltage is applied, one layer out of two charge blocking layers is assigned to an electron blocking layer, while assigning another to a hole blocking layer.

For the hole blocking layer, an electron-accepting organic material can be used.

Examples of the electron-accepting material which can be used include an oxadiazole derivative such as 1,3-bis(4-tert-butylphenyl-1,3,4-oxadiazolyl)phenylene (OXD-7); an anthraquinodimethane derivative; a diphenylquinone derivative; a bathocuproine, a bathophenanthroline and derivatives thereof; a triazole compound; a tris(8-hydroxyquinolinato)aluminum complex; a bis(4-methyl-8-quinolinato)aluminum complex; a distyrylarylene derivative; and a silole compound. Also, a material having a sufficient electron transporting property may be used even if it is not an electron-accepting organic material. That is, a porphyrin-based compound, a styryl-based compound such as DCM (4-dicyanomethylene-2-methyl-6-(4-(dimethylaminostyryl))-4H pyran), and a 4H pyran-based compound can be used.

The thickness of the hole blocking layer is preferably from 10 to 300 nm, more preferably from 30 to 150 nm, still more preferably from 50 to 100 nm, because if this thickness is too small, the effect of suppressing a dark current is decreased, whereas if it is excessively large, the photoelectric conversion efficiency is reduced.

For the electron blocking layer, an electron-donating organic material can be used. Specific examples of the material which can be used include, as a low molecular material, an aromatic diamine compound such as N,N′-bis(3-methylphenyl)-(1,1′-biphenyl)-4,4′-diamine (TPD) and 4,4′-bis[N-(naphthyl)-N-phenylamino]biphenyl (α-NPD), oxazole, oxadiazole, triazole, imidazole, imidazolone, a stilbene derivative, a pyrazolone derivative, tetrahydroimidazole, a polyarylalkane, butadiene, 4,4′,4″-tris(N-(3-methylphenyl)N-phenylamino)triphenylamine (m-MTDATA), a porphyrin compound such as porphin, copper tetraphenylporphin, phthalocyanine, copper phthalocyanine and titanium phthalocyanine oxide, a triazole derivative, an oxadiazole derivative, an imidazole derivative, a polyarylalkane derivative, a pyrazoline derivative, a pyrazolone derivative, a phenylenediamine derivative, an anilamine derivative, an amino-substituted chalcone derivative, an oxazole derivative, a styrylanthracene derivative, a fluorenone derivative, a hydrazone derivative, and a silazane derivative; and, as a polymer material, a polymer such as phenylenevinylene, fluorene, carbazole, indole, pyrene, pyrrole, picolin, thiophene, acetylene and diacetylene, and a derivative thereof. A compound having a sufficient hole transporting property may be used even if it is not an electron-donating compound.

The thickness of the electron blocking layer is preferably from 10 to 300 nm, more preferably from 30 to 150 nm, still more preferably from 50 to 100 nm, because if this thickness is too small, the effect of suppressing a dark current is decreased, whereas if it is excessively large, the photoelectric conversion efficiency is reduced.

In order to improve the photoelectric conversion efficiency, the value obtained by dividing the voltage externally applied between the upper electrode 15 and the lower electrode 11 by the distance from the upper electrode 15 to the lower electrode 11 is preferably from 1.0×10⁵ to 1.0×10⁶ V/cm.

According to the photoelectric conversion element of this embodiment, a crystal layer 16 is provided between the upper electrode 15 containing a transparent electrode material and the photoelectric conversion layer 12, and the crystal layer 16 relieves a stress produced due to the transparent electrode material. For example, in the case where a compressive stress acts on the transparent electrode material, the crystal layer is composed of a material capable of generating a tensile stress to act in the direction opposite the direction in which the compressive stress acts, whereby mutual stresses at the interface between the upper electrode 15 containing a transparent electrode material and the crystal layer 16 can cancel each other. Once the stress of the transparent electrode material is relieved in this way, when the crystal layer 16 and the photoelectric conversion layer 12 are formed as an organic material layer, good adherence can be kept between the organic material layer and the upper electrode 15 and at the same time, distortion of the photoelectric conversion layer 12 can be reduced, as a result, deterioration of the photoelectric conversion efficiency can be suppressed. Thanks to such an effect, the thickness of an ITO thin layer or the like constituting the upper electrode 15 can be increased. The definition of the stress is described later.

As for the material of the crystal layer 16, any material may be selected as long as it can relieve a stress produced due to a transparent electrode material. For example, in the case where a compressive stress is produced in the transparent electrode material, a material having a tensile stress is used for the crystal layer 16. In the case of using ITO as the transparent electrode material, pentacene, naphthalocyanine, phthalocyanine and a pentacene derivative (e.g., p-sexiphenyl, dibenzopentacene, benzochrysene), each having a tensile stress, are preferably used for the crystal layer 16.

The thickness of the crystal layer 16 is preferably from 20 to 50 nm, because if the thickness is less than 20 nm, the material constituting the crystal layer 16 is in an island state and cannot perfectly cover the photoelectric conversion layer and a portion allowing the photoelectric conversion layer to contact with the upper electrode is produced, as a result, the internal stress of the upper electrode cannot be completely relieved and the photoelectric conversion efficiency is reduced, whereas if the thickness exceeds 50 nm, the responsivity as a bulk of the stress relieving layer is not ignorable and the response speed is reduced.

The stress as used herein is described below.

The stress (also called a layer stress, hereinafter simply referred to as a “stress”) of a thin layer including the upper electrode 15 and the like consists of a thermal stress and a true stress. The thermal stress is attributable to a difference in the thermal expansion coefficient. For example, this stress changes due to a difference between the temperature during layer deposition and the temperature during measurement. The true stress is a stress possessed by the thin layer itself and has the same meaning as an internal stress. Here, assuming that the thermal stress is σ_{T}, the true stress is σᵢ and the total stress of the thin layer is σ, σ=σ_{T}+σᵢ is established. The total stress includes two kinds of stresses, that is, a compressive stress and a tensile stress.

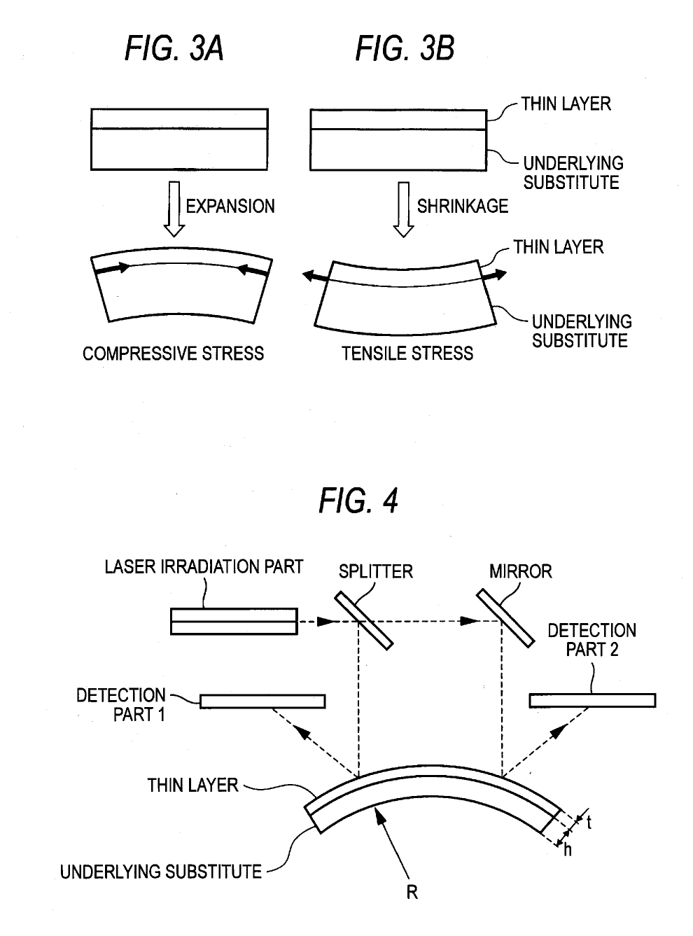

FIGS. 3A and 3B are views schematically showing a force acting on a thin layer deposited on a substrate. In FIG. 3A, the direction of the compressive stress acting on the thin layer when the substrate having formed thereon a thin layer is expanded, is shown by arrows. As shown in FIG. 3A, when a substrate is warped to protrude on the side where a thin layer is deposited, the thin layer deposited on the substrate expands and a force to compress acts on the thin layer tightly adhering to the substrate. This force is a compressive stress.

In FIG. 3B, the direction of the tensile stress acting on the thin layer when a substrate having formed thereon a thin layer is expanded, is shown by arrows. As shown in FIG. 3B, when a substrate is warped to dent on the side where a thin layer is deposited, the thin layer deposited on the substrate shrinks and a force to extend acts on the thin layer tightly adhering to the substrate. This force is a tensile stress.

Here, the compressive force and tensile force of the thin layer affect the amount of warpage of the substrate. Based on the amount of warpage of the substrate, the stress can be measured using an optical lever method. FIG. 4 is a configuration example of the apparatus for measuring the amount of warpage of the substrate. This lever comprises a laser irradiation part for irradiating laser light, a splitter capable of reflecting some light out of light irradiated from the laser irradiation part and at the same time, transmitting other light, and a mirror capable of reflecting light transmitted through the splitter. A thin layer to be measured is deposited on one surface of an underlying substrate. Light reflected by the splitter is irradiated on the thin layer of the underlying substrate, and the reflection angle of light reflected on the thin layer surface is detected by a detection part 1. Light reflected by the mirror is irradiated on the thin layer of the underlying substrate, and the reflection angle of light reflected on the thin layer is detected by a detection part 2. Incidentally, FIG. 4 shows an example of measuring the compressive force acting on the thin layer by warping the underlying substrate to protrude the surface on the side where the thin layer is deposited. Here, the thickness of the underlying substrate is indicated by h, and the thickness of the thin layer is indicated by t.

The procedure for measuring the stress is described below.

As to the apparatus used in the measurement, for example, a thin layer stress measuring apparatus, FLX-2320-S, manufactured by Toho Technology Corporation can be used. The measurement conditions in using this apparatus are shown below.

### (Laser Light)

Laser used: KLA-Tencor-2320-S
Laser output: 4 mW
Laser wavelength: 670 nm
Scanning speed: 30 mm/s

### (Underlying Substrate)

Material of substrate: silicon (Si)

### Azimuth: <100>

Type: p-type (dopant: boron)

### Thickness: 250±25 μm or 280±25 μm

### (Measurement Procedure)

The amount of warpage of the underlying substrate on which a thin layer is deposited is previously measured, and the curvature radius R1 is determined. Subsequently, a thin layer is deposited on one surface of the underlying substrate, the amount of warpage of the underlying substrate is measured, and the curvature radius R2 is determined. Here, as for the amount of warpage, the underlying substrate surface on the side where the thin layer is formed is scanned with a laser as shown in FIG. 4, and the amount of warpage is calculated from the reflection angle of laser light reflected from the underlying substrate. Based on the amount of warpage, the curvature radius R=R1·R2/(R1−R2) is calculated.

Thereafter, the stress of the thin layer is calculated according to the calculating formula. The stress of the thin layer is expressed in the unit of Pa. A negative value indicates the compressive stress, and a positive value indicates the tensile stress. Incidentally, the method for measuring the stress of the thin layer is not particularly limited, and a known method can be used.

### (Calculating Formula of Thin Layer Stress)

σ=E×h²/(1−v)Rt

wherein

E/(1−v): the biaxial elastic coefficient (Pa) of the underlying substrate,

h: the thickness (m) of the underlying substrate,

t: the thickness (m) of the thin layer,

R: the curvature radius (m) of the underlying substrate, and

σ: the average stress (Pa) of the thin layer.

Configuration examples of an imaging device equipped with the photoelectric conversion element are described below. In the following configuration examples, the members and the like having the same configuration/action as the members described above are indicated by the same or like symbols or numerical references in the figure, and their description is simplified or omitted.

### First Configuration Example of Imaging Device

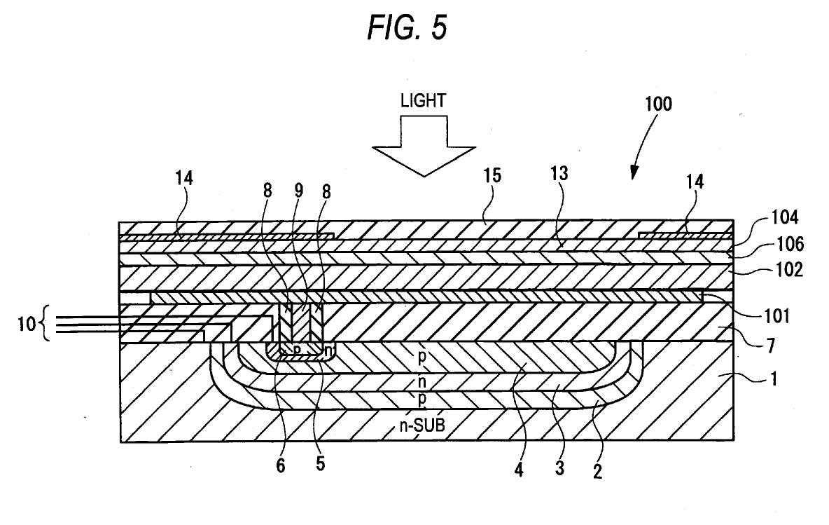

FIG. 5 is a cross-sectional schematic view of one pixel portion of an imaging device. In FIG. 5, the same constitutions as in FIGS. 1 and 2 are indicated by the same symbols or numerical references.

In the imaging device 100, a large number of pixels each constituting one pixel are disposed in an array manner on the same plane, and one-pixel data of the image data can be produced by the signal obtained from the one pixel.

One pixel of the imaging device shown in FIG. 5 contains an n-type silicon substrate 1, a transparent insulating layer 7 formed on the n-type silicon substrate 1 and a photoelectric conversion element consisting of a lower electrode 101 formed on the insulating layer 7, a photoelectric conversion layer 102 formed on the lower electrode 101, a crystal layer 106 formed on the photoelectric conversion layer 102 and a transparent electrode material-containing upper electrode 104 formed on the crystal layer 106. A light-shielding layer 14 having provided therein an opening is formed on the photoelectric conversion element, and a transparent insulating layer 15 is formed on the upper electrode 104. Here, the crystal layer 106 is composed of a stress relieving layer capable of relieving the stress of the transparent electrode material contained in the upper electrode 104 provided on the crystal layer 106. As for the material of the crystal layer 106 and the transparent electrode material, those described above in relation to the configuration of the photoelectric conversion element are preferably used.

Inside of the n-type silicon substrate 1, a p-type impurity region (hereinafter simply referred to as “p region”) 4, an n-type impurity region (hereinafter simply referred to as “n region”) 3 and a p region 2 are formed in order of increasing the depth. In the p region 4, a high-concentration p region 6 is formed in the surface part of the portion light-shielded by the light-shielding layer 14, and the p region 6 is surrounded by an n region 5.

The depth of the pn junction plane between the p region 4 and the n region 3 from the surface of the n-type silicon substrate 1 is set to a depth at which blue light is absorbed (about 0.2 μm). Therefore, the p region 4 and the n region 3 form a photodiode (B photodiode) of absorbing blue light and accordingly accumulating electric charges.

The depth of the pn junction plane between the p region 2 and the n-type silicon substrate 1 from the surface of the n-type silicon substrate 1 is set to a depth at which red light is absorbed (about 2 μm). Therefore, the p region 2 and the n-type silicon substrate 1 form a photodiode (R photodiode) of absorbing red light and accordingly accumulating electric charges.

The p region 6 is electrically connected to the lower electrode 101 via a connection part 9 formed in the opening bored through the insulating layer 7. A hole trapped by the lower electrode 101 recombines with an electron in the p region 6 and therefore, the number of electrons accumulated in the p region 6 on resetting decreases according to the number of holes trapped. The connection part 9 is electrically insulated by an insulating layer 8 from portions except for the lower electrode 101 and the p region 6.

The electrons accumulated in the p region 2 are converted into signals according to the electric charge amount by an MOS circuit composed of a p-channel MOS transistor (not shown) formed inside of the n-type silicon substrate 1, the electrons accumulated in the p region 4 are converted into signals according to the electric charge amount by an MOS circuit composed of a p-channel MOS transistor (not shown) formed inside of the n region 3, the electrons accumulated in the p region 6 are converted into signals according to the electric charge amount by an MOS circuit composed of a p-channel MOS transistor (not shown) formed inside of the n region 5, and these signals are output to the outside of the imaging device 100. Each MOS circuit is connected to a signal reading pad (not shown) by a wiring 10. Incidentally, when an electrode for collecting is provided in the p region 2 and p region 4 and a predetermined reset potential is applied, each region is depleted and the capacity of each pn junction part becomes an unboundedly small value, whereby the capacity produced in the junction plane can be made extremely small.

Thanks to such a configuration, G light can be photoelectrically converted by the photoelectric conversion layer 102, and B light and R light can be photoelectrically converted by the B photodiode and the R photodiode, respectively, in the n-type silicon substrate 1. Also, since G light is first absorbed in the upper part, excellent color separation is achieved between B-G and between G-R. This is a greatly excellent point in comparison with an imaging device of the type where three PDs are stacked inside of a silicon substrate and all of BGR lights are separated inside of the silicon substrate.

In the imaging device 100 of this embodiment, a stress relieving layer composed of a crystal layer capable of relieving the stress of the transparent electrode material is provided between the upper electrode 104 and the photoelectric conversion layer 102, so that mutual stresses at the interface of the transparent electrode material-containing upper electrode 104 with the crystal layer 106 can cancel each other. Once the stress of the transparent electrode material is relieved in this way, when the crystal layer 106 and the photoelectric conversion layer 102 are formed as an organic material layer, good adherence can be kept between the organic material layer and the upper electrode 104 and at the same time, distortion of the photoelectric conversion layer 102 can be reduced, as a result, deterioration of the photoelectric conversion efficiency can be suppressed.

### Second Configuration Example of Imaging Device

In this embodiment, instead of a configuration where two photodiodes are stacked inside of a silicon substrate 1 as in the imaging device of FIG. 5, two diodes are arrayed in the direction perpendicular to the incidence direction of incident light so that lights of two colors can be detected inside of the n-type silicon substrate.

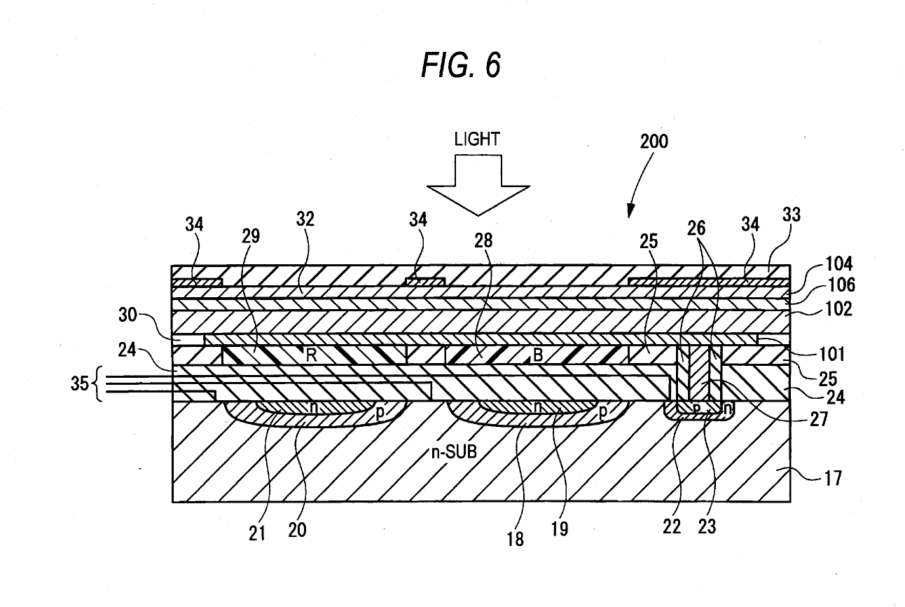

FIG. 6 is a cross-sectional schematic view of one pixel portion of an imaging device of this configuration example. In FIG. 6, the same constitutions as in FIG. 1 are indicated by the same symbols or numerical references.

One pixel of the imaging device 200 shown in FIG. 6 contains an n-type silicon substrate 17 and a photoelectric conversion element consisting of a lower electrode 101 formed above the n-type silicon substrate 17, a photoelectric conversion layer 102 formed on the lower electrode 101, a crystal layer 106 formed on the photoelectric conversion layer 102, and an upper electrode 104 formed on the crystal layer 106. A light-shielding layer 34 having provided therein an opening is formed on the photoelectric conversion element, and a transparent insulating layer 33 is formed on the upper electrode 104. Here, the crystal layer 106 is composed of a stress relieving layer capable of relieving the stress of the transparent electrode material contained in the upper electrode 104 provided on the crystal layer 106. As for the material of the crystal layer 106 and the transparent electrode material, those described above in relation to the configuration of the photoelectric conversion element are preferably used.

On the surface of the n-type silicon substrate 17 below the opening of the light-shielding layer 34, a photodiode consisting of an n region 19 and a p region 18 and a photodiode consisting of an n region 21 and a p region 20 are formed in juxtaposition on the surface of the n-type silicon substrate 17. An arbitrary direction on the n-type silicon substrate 17 surface becomes the direction perpendicular to the incidence direction of incident light.

Above the photodiode consisting of an n region 19 and a p region 18, a color filter 28 capable of transmitting B light is formed via a transparent insulating layer 24, and the lower electrode 101 is formed thereon. Above the photodiode consisting of an n region 21 and a p region 20, a color filter 29 capable of transmitting R light is formed via the transparent insulating layer 24, and the lower electrode 101 is formed thereon. The peripheries of color filters 28 and 29 are covered with a transparent insulating layer 25.

The photodiode consisting of an n region 19 and a p region 18 functions as an in-substrate photoelectric conversion part that absorbs B light transmitted through the color filter 28, generates electrons according to the light absorbed, and accumulates the generated electrons in the p region 18. The photodiode consisting of an n region and a p region 20 functions as an in-substrate photoelectric conversion part that absorbs R light transmitted through the color filter 29, generates electrons according to the light absorbed, and accumulates the generated holes in the p region 20.

In the portion shielded from light by the light-shielding layer 34 on the n-type silicon substrate 17 surface, a p region 23 is formed, and the periphery of the p region 23 is surrounded by an n region 22.

The p region 23 is electrically connected to the lower electrode 101 via a connection part 27 formed in the opening bored through the insulating layers 24 and 25. A hole trapped by the lower electrode 101 recombines with an electron in the p region 23 and therefore, the number of electrons accumulated in the p region 23 on resetting decreases according to the number of holes trapped. The connection part 27 is electrically insulated by an insulating layer 26 from portions except for the lower electrode 101 and the p region 23.

The electrons accumulated in the p region 18 are converted into signals according to the electric charge amount by an MOS circuit composed of a p-channel MOS transistor (not shown) formed inside of the n-type silicon substrate 17, the electrons accumulated in the p region 20 are converted into signals according to the electric charge amount by an MOS circuit composed of a p-channel MOS transistor (not shown) formed inside of the n-type silicon substrate 17, the electrons accumulated in the p region 23 are converted into signals according to the electric charge amount by an MOS circuit composed of an n-channel MOS transistor (not shown) formed inside of the n region 22, and these signals are output to the outside of the imaging device 200. Each MOS circuit is connected to a signal reading pad (not shown) by a wiring 35.

Incidentally, instead of MOS circuits, the signal reading part may be composed of CCD and an amplifier, that is, may be a signal reading part where electrons accumulated in the p region 18, p region 20 and p region 23 are read-out into CCD formed inside of the n-type silicon substrate 17 and are then transferred to an amplifier by the CCD and signals according to the electrons transferred are output from the amplifier.

In this way, the signal reading part includes a CCD structure and a CMOS structure, but in view of power consumption, high-speed reading, pixel addition, partial reading and the like, CMOS is preferred.

Incidentally, in FIG. 6, color separation of B light and R light is performed by color filters 28 and 29, but instead of providing color filters 28 and 29, the depth of the pn junction plane between the p region 20 and the n region 21 and the depth of the pn junction plane between the p region 18 and the n region 19 each may be adjusted to absorb R light and B light by respective photodiodes.

An inorganic photoelectric conversion element composed of an inorganic material that absorbs light transmitted through the photoelectric conversion layer 102, generates electric charges according to the light absorbed, and accumulates the electric charges, may also be formed between the n-type silicon substrate 17 and the lower electrode 101 (for example, between the insulating layer 24 and the n-type silicon substrate 17). In this case, an MOS circuit for reading signals according to the electric charges accumulated in a charge accumulation region of the inorganic photoelectric conversion part may be provided inside of the n-type silicon substrate 17 and a wiring 35 may be connected also to this MOS circuit.

Also, there may take a configuration where one photodiode is provided inside of the n-type silicone substrate 17 and a plurality of photoelectric conversion parts are stacked above the n-type silicon substrate 17; a configuration where a plurality of photodiodes are provided inside of the n-type silicon substrate 17 and a plurality of photoelectric conversion parts are stacked above the n-type silicon substrate 17; or when a color image need not be formed, a configuration where one photodiode is provided inside of the n-type silicon substrate 17 and only one photoelectric conversion part is stacked.

In the imaging device 200 of this embodiment, a stress relieving layer composed of a crystal layer capable of relieving the stress of the transparent electrode material is provided between the upper electrode 104 and the photoelectric conversion layer 102, so that mutual stresses at the interface of the transparent electrode material-containing upper electrode 104 with the crystal layer 106 can cancel each other. Once the stress of the transparent electrode material is relieved in this way, when the crystal layer 106 and the photoelectric conversion layer 102 are formed as an organic material layer, good adherence can be kept between the organic material layer and the upper electrode 104 and at the same time, distortion of the photoelectric conversion layer 102 can be reduced, as a result, deterioration of the photoelectric conversion efficiency can be suppressed.

### Third Configuration Example of Imaging Device

The imaging device of this embodiment is configured such that a photodiode is not provided inside of the silicon substrate and a plurality of (here, three) photoelectric conversion elements are stacked above the silicon substrate.

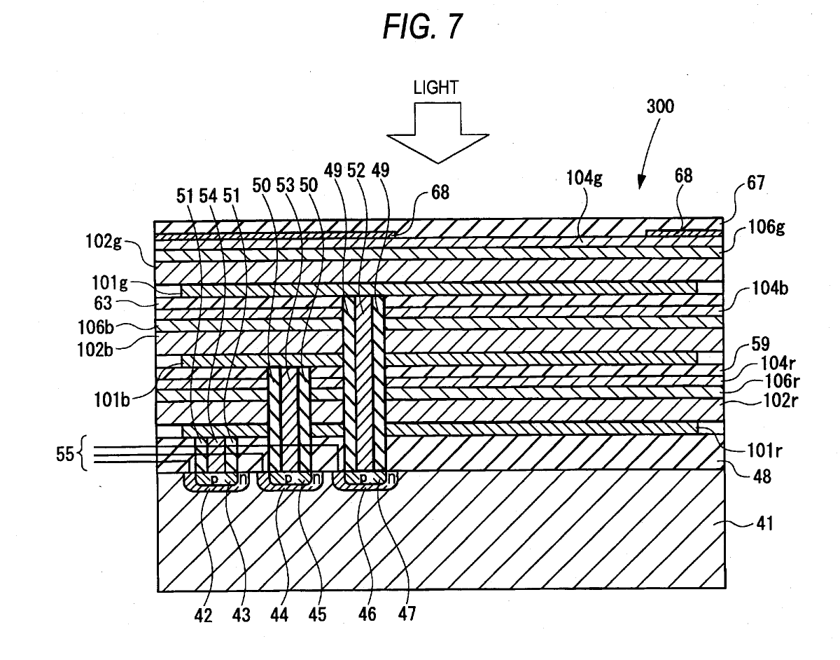

FIG. 7 is a cross-sectional schematic view of one pixel portion of the imaging device of this embodiment.

The imaging device 300 shown in FIG. 7 has a configuration where an R photoelectric conversion element, a B photoelectric conversion element, and a G photoelectric conversion element are stacked in order above a silicon substrate 41.

The R photoelectric conversion element stacked above the silicon substrate 41 comprises a lower electrode 101r, a photoelectric conversion layer 102r formed on the lower electrode 101r, a crystal layer 106r formed on the photoelectric conversion layer 102r, and an upper electrode 104r stacked on the crystal layer 106r.

The B photoelectric conversion element comprises a lower electrode 101b stacked on the upper electrode 104r of the R photoelectric conversion element, a photoelectric conversion layer 102b formed on the lower electrode 101b, a crystal layer 106b formed on the photoelectric conversion layer 102b, and an upper electrode 104b stacked on the crystal layer 106b.

The G photoelectric conversion element comprises a lower electrode 101g stacked on the upper electrode 104b of the B photoelectric conversion element, a photoelectric conversion layer 102g formed on the lower electrode 101g, a crystal layer 106g formed on the photoelectric conversion layer 102g, and an upper electrode 104g stacked on the crystal layer 106g. The imaging device of this configuration example is configured by stacking, in order, an R photoelectric conversion element, a B photoelectric conversion element, and a G photoelectric conversion element.

A transparent insulating layer 59 is formed between the upper electrode 104r of the R photoelectric conversion element and the lower electrode 101b of the B photoelectric conversion element, and a transparent insulating layer 63 is formed between the upper electrode 104b of the B photoelectric conversion element and the lower electrode 101g of the G photoelectric conversion element. A light-shielding layer 68 in the region excluding an opening is formed on the upper electrode 104g of the G photoelectric conversion element, and a transparent insulating layer 67 is formed to cover the upper electrode 104g and the light-shielding layer 68.

The lower electrode, the photoelectric conversion layer, the crystal layer and the upper electrode contained in each of the R, G and B photoelectric conversion elements can have the same configuration as that in the photoelectric conversion element described above. However, the photoelectric conversion layer 102g contains an organic material capable of absorbing green light and generating electrons and holes according to the light absorbed, the photoelectric conversion layer 102b contains an organic material capable of absorbing blue light and generating electrons and holes according to the light absorbed, and the photoelectric conversion layer 102r contains an organic material capable of absorbing red light and generating electrons and holes according to the light absorbed.

In the portion shielded from light by the light-shielding layer 68 on the silicon substrate 41 surface, p regions 43, 45 and 47 are formed, and the peripheries of these regions are surrounded by n regions 42, 44 and 46, respectively.

The p region 43 is electrically connected to the lower electrode 101r via a connection part 54 formed in an opening bored through an insulating layer 48. A hole trapped by the lower electrode 101r recombines with an electron in the p region 43 and therefore, the number of electrons accumulated in the p region 43 on resetting decreases according to the number of holes trapped. The connection part 54 is electrically insulated by an insulating layer 51 from portions except for the lower electrode 101r and the p region 43.

The p region 45 is electrically connected to the lower electrode 101b via a connection part 53 formed in an opening bored through the insulating layer 48, the R photoelectric conversion element and the insulating layer 59. A hole trapped by the lower electrode 101b recombines with an electron in the p region 45 and therefore, the number of electrons accumulated in the p region 45 on resetting decreases according to the number of holes trapped. The connection part 53 is electrically insulated by an insulating layer 50 from portions except for the lower electrode 101b and the p region 45.

The p region 47 is electrically connected to the lower electrode 101g via a connection part 52 formed in an opening bored through the insulating layer 48, the R photoelectric conversion element, the insulating layer 59, the B photoelectric conversion element and the insulating layer 63. A hole trapped by the lower electrode 101g recombines with an electron in the p region 47 and therefore, the number of electrons accumulated in the p region 47 on resetting decreases according to the number of holes trapped. The connection part 52 is electrically insulated by an insulating layer 49 from portions except for the lower electrode 101g and the p region 47.

The electrons accumulated in the p region 43 are converted into signals according to the electric charge amount by an MOS circuit composed of a p-channel MOS transistor (not shown) formed inside of the n region 42, the electrons accumulated in the p region 45 are converted into signals according to the electric charge amount by an MOS circuit composed of a p-channel MOS transistor (not shown) formed inside of the n region 44, the electrons accumulated in the p region 47 are converted into signals according to the electric charge amount by an MOS circuit composed of a p-channel MOS transistor (not shown) formed inside of the n region 46, and these signals are output to the outside of the imaging device 300. Each MOS circuit is connected to a signal reading pad (not shown) by a wiring 55. Incidentally, instead of MOS circuits, the signal reading part may be composed of CCD and an amplifier, that is, may be a signal reading part where electrons accumulated in the p regions 43, 45 and 47 are read-out into CCD formed inside of the silicon substrate 41 and are then transferred to an amplifier by the CCD and signals according to the electrons transferred are output from the amplifier.

In the description above, the photoelectric conversion layer capable of absorbing B light means a layer which can absorb at least light at a wavelength of 400 to 500 nm and in which the absorption factor at a peak wavelength in the wavelength region above is preferably 50% or more. The photoelectric conversion layer capable of absorbing G light means a layer which can absorb at least light at a wavelength of 500 to 600 nm and in which the absorption factor at a peak wavelength in the wavelength region above is preferably 50% or more. The photoelectric conversion layer capable of absorbing R light means a layer which can absorb at least light at a wavelength of 600 to 700 nm and in which the absorption factor at a peak wavelength in the wavelength region above is preferably 50% or more.

The imaging device 300 of this embodiment has a configuration where in each of the R photoelectric conversion element, G photoelectric conversion element and B photoelectric conversion element, a crystal layer 106r, 106g or 106b capable of relieving the stress of the transparent electrode material is provided between the upper electrode 104r, 104g or 104b and the photoelectric conversion layer 102r, 102g or 102b. In each photoelectric conversion element, mutual stress can cancel each other at the interface of the upper electrode 104r, 104g or 104b with the crystal layer 106r, 106g or 106b. In each photoelectric conversion element, once the stress of the transparent electrode material is relieved, when each of the crystal layers 106r, 106g and 106b and each of the photoelectric conversion layers 102r, 102g and 102b are formed as an organic material layer, good adherence can be kept between the organic material layer and the upper electrode 104r, 104g or 104b and at the same time, distortion of the photoelectric conversion layers 102r, 102g and 102b can be reduced, as a result, deterioration of the photoelectric conversion efficiency can be suppressed.

Next, measurement is performed to confirm optical properties of a photoelectric conversion element configured to contain a crystal layer between an upper electrode and a photoelectric conversion layer, in contrast to a photoelectric conversion element configured to contain an upper electrode on an amorphous charge blocking layer. In this measurement, it is demonstrated based on the following Examples and Comparative Examples that as compared with the amorphous charge blocking layer, the crystal layer affords good photoelectric conversion efficiency in a low electric field and is highly effective in suppressing a layer distortion attributable to a stress of an ITO electrode.

With respect to an ITO thin layer and a layer composed of a crystal material, the stress is measured according to the above-described measuring method, and the values obtained are shown below. As regards the measurement of the following stress values, the layer thickness (nm) and thin layer stress value (MPa) for each material are shown below, and by performing the measurement three or four times for each material in view of reproducibility, the average of stress values is calculated.

TABLE 1

| | | Layer | Thin Layer | Average |
|---|---|---|---|---|
| Number of | | Thickness | Stress | value |
| Measurements | Material Name | (nm) | Value (MPa) | (MPa) |
| 1 | pentacene | 50 | 45 | 36.25 |
| 2 | | | 27 | |
| 3 | | | 36 | |
| 4 | | | 37 | |
| 1 | phthalocyanine | 50 | 45 | 36.0 |
| 2 | | | 27 | |
| 3 | | | 36 | |
| 1 | naphthalocyanine | 50 | 6.9 | 9.39 |
| 2 | | | 12.5 | |
| 3 | | | 8.8 | |
| 1 | hexabenzobenzene | 50 | 41.5 | 40 |
| 2 | | | 56.1 | |
| 3 | | | 22.1 | |
| 1 | ITO | 5 | −477 | −457 |
| 2 | | | −383 | |
| 3 | | | −511 | |
| 1 | dibenzochrysene | 50 | −31.3 | −26 |
| 2 | | | −37.2 | |
| 3 | | | −9.6 | |
| 1 | molybdenum oxide | 20 | −69 | −52.9 |
| 2 | | | −60 | |
| 3 | | | −29 | |

### Example 1

A glass substrate with an ITO electrode was washed, and the glass substrate was transferred to an organic deposition chamber. The pressure in the chamber was reduced to 1×10⁻⁴ Pa or less, and while rotating the substrate holder, chemical formulae 1 and 2 shown below were co-deposited (co-evaporated) on the ITO electrode by a resistance heating deposition method at a deposition rate of from 1.6×10⁻¹ to 1.8×10⁻¹ nm/sec and from 2.5×10⁻¹ to 2.8×10⁻¹ nm/sec, respectively, to form a photoelectric conversion layer having a thickness of 400 nm. Thereafter, while keeping at 1×10⁻⁴ Pa or less in the chamber, chemical formula 3 shown below was deposited at a deposition rate of from 1.0×10⁻¹ to 1.2×10⁻¹ nm/sec to a thickness of 300 nm. Furthermore, while keeping at 1×10⁻⁴ Pa or less in the chamber, chemical formula 4 shown below was deposited at a deposition rate of from 1.0×10⁻¹ to 1.2×10⁻¹ nm/sec to a thickness of 50 nm. The resulting substrate was transported to a sputtering chamber, and ITO as an opposite electrode was sputtered on the charge blocking layer by RF magnetron sputtering to a thickness of 5 nm. Without exposing to atmosphere, the substrate was transported to a glove box in which each of water and oxygen was kept at 1 ppm or less, and encapsulated using a UV-curable resin in a glass encapsulation can filled with an adsorbent. The thus-fabricated element was measured for the external quantum efficiency (IPCE) at a wavelength of 500 nm from the value of dark current flowing during light irradiation and the value of photocurrent flowing during light irradiation when an external electric field up to 1.5×10⁵ V/cm was applied to the element. As for IPCE, the quantum efficiency was calculated using a value obtained by subtracting the dark current value from the photocurrent value. Light irradiated was 50 μW/cm².

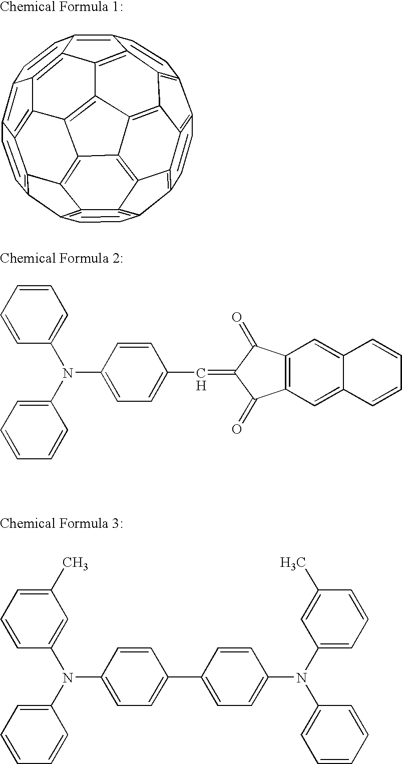

### Example 2

A glass substrate with an ITO electrode was washed, and the glass substrate was transferred to an organic deposition chamber. The pressure in the chamber was reduced to 1×10⁻⁴ Pa or less, and while rotating the substrate holder, chemical formulae 1 and 2 were co-deposited (co-evaporated) on the ITO electrode by a resistance heating deposition method at a deposition rate of from 1.6×10⁻¹ to 1.8×10⁻¹ nm/sec and from 2.5×10⁻¹ to 2.8×10⁻¹ nm/sec, respectively, to form a photoelectric conversion layer having a thickness of 400 nm. Thereafter, while keeping at 1×10⁻⁴ Pa or less in the chamber, chemical formula 3 was deposited at a deposition rate of from 1.0×10⁻¹ to 1.2×10⁻¹ nm/sec to a thickness of 300 nm. Furthermore, while keeping at 1×10⁻⁴ Pa or less in the chamber, chemical formula 4 shown below was deposited at a deposition rate of from 1.0×10⁻⁴ to 1.2×10⁻¹ nm/sec to a thickness of 50 nm. The resulting substrate was transported to a sputtering chamber, and ITO as an opposite electrode was sputtered on the charge blocking layer by RF magnetron sputtering to a thickness of 10 nm. Without exposing to atmosphere, the substrate was transported to a glove box in which each of water and oxygen was kept at 1 ppm or less, and encapsulated using a UV-curable resin in a glass encapsulation can filled with an adsorbent.

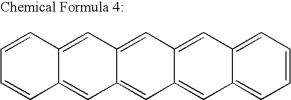

### Example 3

A glass substrate with an ITO electrode was washed, and the glass substrate was transferred to an organic deposition chamber. The pressure in the chamber was reduced to 1×10⁻⁴ Pa or less, and while rotating the substrate holder, chemical formulae 1 and 2 were co-deposited (co-evaporated) on the ITO electrode by a resistance heating deposition method at a deposition rate of from 1.6×10⁻¹ to 1.8×10⁻¹ nm/sec and from 2.5×10⁻¹ to 2.8×10⁻¹ nm/sec, respectively, to form a photoelectric conversion layer having a thickness of 400 nm. Thereafter, while keeping at 1×10⁻⁴ Pa or less in the chamber, chemical formula 3 was deposited at a deposition rate of from 1.0×10⁻¹ to 1.2×10⁻¹ nm/sec to a thickness of 300 nm. Furthermore, while keeping at 1×10⁻⁴ Pa or less in the chamber, chemical formula 5 shown below was deposited at a deposition rate of from 1.0×10⁻¹ to 1.2×10⁻¹ nm/sec to a thickness of 50 nm. The resulting substrate was transported to a sputtering chamber, and ITO as an opposite electrode was sputtered on the charge blocking layer by RF magnetron sputtering to a thickness of 5 nm. Without exposing to atmosphere, the substrate was transported to a glove box in which each of water and oxygen was kept at 1 ppm or less, and encapsulated using a UV-curable resin in a glass encapsulation can filled with an adsorbent.

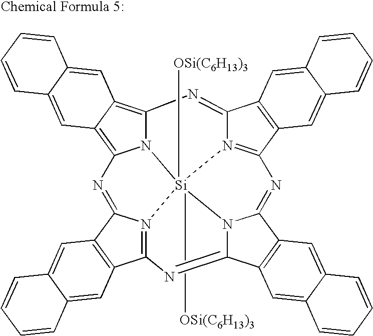

### Example 4

A glass substrate with an ITO electrode was washed, and the glass substrate was transferred to an organic deposition chamber. The pressure in the chamber was reduced to 1×10⁻⁴ Pa or less, and while rotating the substrate holder, chemical formulae 1 and 2 were co-deposited (co-evaporated) on the ITO electrode by a resistance heating deposition method at a deposition rate of from 1.6×10⁻¹ to 1.8×10⁻¹ nm/sec and from 2.5×10⁻¹ to 2.8×10⁻¹ nm/sec, respectively, to form a photoelectric conversion layer having a thickness of 400 nm. Thereafter, while keeping at 1×10⁻⁴ Pa or less in the chamber, chemical formula 3 was deposited at a deposition rate of from 1.0×10⁻¹ to 1.2×10⁻¹ nm/sec to a thickness of 300 nm. Furthermore, while keeping at 1×10⁻⁴ Pa or less in the chamber, chemical formula 5 was deposited at a deposition rate of from 1.0×10⁻¹ to 1.2×10⁻¹ nm/sec to a thickness of nm. The resulting substrate was transported to a sputtering chamber, and ITO as an opposite electrode was sputtered on the charge blocking layer by RF magnetron sputtering to a thickness of 10 nm. Without exposing to atmosphere, the substrate was transported to a glove box in which each of water and oxygen was kept at 1 ppm or less, and encapsulated using a UV-curable resin in a glass encapsulation can filled with an adsorbent.

### Example 5

A glass substrate with an ITO electrode was washed, and the glass substrate was transferred to an organic deposition chamber. The pressure in the chamber was reduced to 1×10⁻⁴ Pa or less, and while rotating the substrate holder, chemical formulae 1 and 2 were co-deposited (co-evaporated) on the ITO electrode by a resistance heating deposition method at a deposition rate of from 1.6×10⁻¹ to 1.8×10⁻¹ nm/sec and from 2.5×10⁻¹ to 2.8×10⁻¹ nm/sec, respectively, to form a photoelectric conversion layer having a thickness of 400 nm. Thereafter, while keeping at 1×10⁻⁴ Pa or less in the chamber, chemical formula 3 was deposited at a deposition rate of from 1.0×10⁻¹ to 1.2×10⁻¹ nm/sec to a thickness of 300 nm. The substrate was then transferred to a metal deposition chamber, and while keeping at 1×10⁻⁴ Pa or less in the chamber, chemical formula 6 shown below was deposited at a deposition rate of from 1.0×10⁻¹ to 1.2×10⁻¹ nm/sec to a thickness of 50 nm. The resulting substrate was transported to a sputtering chamber, and ITO as an opposite electrode was sputtered on the charge blocking layer by RF magnetron sputtering to a thickness of 5 nm. Without exposing to atmosphere, the substrate was transported to a glove box in which each of water and oxygen was kept at 1 ppm or less, and encapsulated using a UV-curable resin in a glass encapsulation can filled with an adsorbent.

MoO₃ Chemical Formula 6

### Example 6

A glass substrate with an ITO electrode was washed, and the glass substrate was transferred to an organic deposition chamber. The pressure in the chamber was reduced to 1×10⁻⁴ Pa or less, and while rotating the substrate holder, chemical formulae 1 and 2 were co-deposited (co-evaporated) on the ITO electrode by a resistance heating deposition method at a deposition rate of from 1.6×10⁻¹ to 1.8×10⁻¹ nm/sec and from 2.5×10⁻¹ to 2.8×10⁻¹ nm/sec, respectively, to form a photoelectric conversion layer having a thickness of 400 nm. Thereafter, while keeping at 1×10⁻⁴ Pa or less in the chamber, chemical formula 3 was deposited at a deposition rate of from 1.0×10⁻¹ to 1.2×10⁻¹ nm/sec to a thickness of 300 nm. The substrate was then transferred to a metal deposition chamber, and while keeping at 1×10⁻⁴ Pa or less in the chamber, chemical formula 6 was deposited at a deposition rate of from 1.0×10⁻¹ to 1.2×10⁻¹ nm/sec to a thickness of nm. The resulting substrate was transported to a sputtering chamber, and ITO as an opposite electrode was sputtered on the charge blocking layer by RF magnetron sputtering to a thickness of 10 nm. Without exposing to atmosphere, the substrate was transported to a glove box in which each of water and oxygen was kept at 1 ppm or less, and encapsulated using a UV-curable resin in a glass encapsulation can filled with an adsorbent.

### Example 7

A glass substrate with an ITO electrode was washed, and the glass substrate was transferred to an organic deposition chamber. The pressure in the chamber was reduced to 1×10⁻⁴ Pa or less, and while rotating the substrate holder, chemical formulae 1 and 2 were co-deposited (co-evaporated) on the ITO electrode by a resistance heating deposition method at a deposition rate of from 1.6×10⁻¹ to 1.8×10⁻¹ nm/sec and from 2.5×10⁻¹ to 2.8×10⁻¹ nm/sec, respectively, to form a photoelectric conversion layer having a thickness of 400 nm. The substrate was then transferred to a metal deposition chamber, and while keeping at 1×10⁻⁴ Pa or less in the chamber, chemical formula 6 was deposited at a deposition rate of from 1.0×10⁻¹ to 1.2×10⁻¹ nm/sec to a thickness of 50 nm. This Example is a configuration where a crystal layer having a charge blocking function is provided on the photoelectric conversion layer. The resulting substrate was transported to a sputtering chamber, and ITO as an opposite electrode was sputtered on the crystal layer by RF magnetron sputtering to a thickness of 5 nm. Without exposing to atmosphere, the substrate was transported to a glove box in which each of water and oxygen was kept at 1 ppm or less, and encapsulated using a UV-curable resin in a glass encapsulation can filled with an adsorbent.

### Comparative Example 1

Using a glass substrate with an ITO electrode after washing similarly to Example 1, chemical formulae 1 and 2 were co-deposited (co-evaporated) under the same conditions as in Examples by a resistance heating deposition method at a deposition rate of from 1.6×10⁻¹ to 1.8×10⁻¹ nm/sec and from 2.5×10⁻¹ to 2.8×10⁻¹ nm/sec, respectively, to form a photoelectric conversion layer having a thickness of 400 nm. Furthermore, chemical formula 3 was deposited by a resistance heating deposition method at a deposition rate of from 1.0×10⁻¹ to 1.2×10⁻¹ nm/sec to a thickness of 300 nm. The resulting substrate was transported to a sputtering chamber, and ITO as an opposite electrode was sputtered on the charge blocking layer by RF magnetron sputtering to a thickness of 5 nm. After encapsulation, the photocurrent, dark current and IPCE were measured.

### Comparative Example 2

Using a substrate with an ITO electrode after washing similarly to Example 1, chemical formulae 1 and 2 were co-deposited (co-evaporated) under the same conditions as in Examples by a resistance heating deposition method at a deposition rate of from 1.6×10⁻¹ to 1.8×10⁻¹ nm/sec and from 2.5×10⁻¹ to 2.8×10⁻¹ nm/sec, respectively, to form a photoelectric conversion layer having a thickness of 400 nm. Furthermore, chemical formula 3 was deposited by a resistance heating deposition method at a deposition rate of from 1.0×10⁻¹ to 1.2×10⁻¹ nm/sec to a thickness of 300 nm. The resulting substrate was transported to a sputtering chamber, and ITO as an opposite electrode was sputtered on the charge blocking layer by RF magnetron sputtering to a thickness of 10 nm. After encapsulation, the photocurrent, dark current and IPCE were measured.

### Comparative Example 3

Using a substrate with an ITO electrode after washing similarly to Example 1, chemical formulae 1 and 2 were co-deposited (co-evaporated) under the same conditions as in Examples by a resistance heating deposition method at a deposition rate of from 1.6×10⁻¹ to 1.8×10⁻¹ nm/sec and from 2.5×10⁻¹ to 2.8×10⁻¹ nm/sec, respectively, to form a photoelectric conversion layer having a thickness of 400 nm. Thereafter, chemical formula 3 was deposited by a resistance heating deposition method at a deposition rate of from 1.0×10⁻¹ to 1.2×10⁻¹ nm/sec to a thickness of 300 nm. Furthermore, while keeping at 1×10⁻⁴ Pa in the chamber, chemical formula 7 (D3736, dibenzochrysene) shown below was deposited at a deposition rate of from 1.0×10⁻¹ to 1.2×10⁻¹ nm/sec to a thickness of 50 nm. The resulting substrate was transported to a sputtering chamber, and ITO as an opposite electrode was sputtered on the charge blocking layer by RF magnetron sputtering to a thickness of 10 nm. After encapsulation, the photocurrent, dark current and IPCE were measured. This Comparative Example is a configuration where a crystal layer having no stress relieving function is provided on the photoelectric conversion layer.

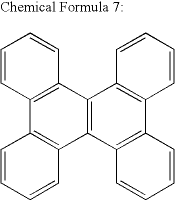

Configurations of photoelectric conversion elements of Examples and Comparative Examples are shown below. The numerical value in the parenthesis is the thickness (unit: nm) of the layer. Also, the charge blocking layer shown by chemical formula 3 of Examples 1 to 6 and Comparative Examples 1, 2 and 3 is an amorphous layer (non-crystal layer). The layer composed of chemical formula 4 in Examples 1 and 2, the layer composed of chemical formula 5 in Examples 3 and 4, the layer composed of chemical formula 6 in Examples 5 to 7, and the layer composed of chemical formula 7 in Comparative Example 3 all are a crystal layer. In the Table, the mark “-” indicates that the pertinent layer is not provided.

TABLE 2

| Example 3 | ITO | chemical | chemical formula | chemical | ITO |
|---|---|---|---|---|---|
| | (100) | formulae 1 | 3, amorphous | formula 5 | (5) |
| | | and 2 (400) | layer (300) | (50) | |
| Example 4 | ITO | chemical | chemical formula | chemical | ITO |
| | (100) | formulae 1 | 3, amorphous | formula 5 | (10) |
| | | and 2 (400) | layer (300) | (50) | |
| Example 5 | ITO | chemical | chemical formula | chemical | ITO |
| | (100) | formulae 1 | 3, amorphous | formula 6 | (5) |
| | | and 2 (400) | layer (300) | (50) | |
| Example 6 | ITO | chemical | chemical formula | chemical | ITO |
| | (100) | formulae 1 | 3, amorphous | formula 6 | (10) |
| | | and 2 (400) | layer (300) | (50) | |
| Example 7 | ITO | chemical | — | chemical | ITO |
| | (100) | formulae 1 | | formula 6 | (5) |
| | | and 2 (400) | | (50) | |
| Comparative | ITO | chemical | chemical formula | — | ITO |
| Example 1 | (100) | formulae 1 | 3, amorphous | | (5) |
| | | and 2 (400) | layer (300) | | |
| Comparative | ITO | chemical | chemical formula | — | ITO |
| Example 2 | (100) | formulae 1 | 3, amorphous | | (10) |
| | | and 2 (400) | layer (300) | | |
| Comparative | ITO | chemical | chemical formula | chemical | ITO |
| Example 3 | (100) | formulae 1 | 3, amorphous | formula 7 | (5) |
| | | and 2 (400) | layer (300) | (50) | |

The results of this measurement are shown in the following Table 3, in which the dark current density with respect to the electric field intensity (1.0×10⁵ V/cm) between electrodes for each of photoelectric conversion elements of Examples and Comparative Examples, and the photoelectric conversion efficiency (IPCE) with respect to the electric field intensity (1.0×10⁵ V/cm) between electrodes for each of photoelectric conversion elements of Examples and Comparative Examples are shown.

TABLE 3

| | Dark current | |
|---|---|---|
| | density (A/cm²) | IPCE (%) |
| Comparative | 3.82 × 10⁻⁸ | 26.3 |
| Example 1 | | |
| Comparative | 9.45 × 10⁻⁸ | 13.8 |
| Example 2 | | |
| Comparative | 2.71 × 10⁻⁸ | 22.0 |
| Example 3 | | |
| Example 1 | 5.53 × 10⁻⁸ | 41.9 |
| Example 2 | 3.72 × 10⁻⁸ | 41.2 |
| Example 3 | 1.08 × 10⁻⁹ | 41.1 |
| Example 4 | 1.55 × 10⁻⁹ | 41.2 |
| Example 5 | 5.66 × 10⁻⁸ | 41.6 |
| Example 6 | 1.10 × 10⁻⁷ | 39.5 |
| Example 7 | 8.79 × 10⁻⁹ | 51.8 |

In Examples 1 to 6, distortion attributable to the stress of the upper electrode can be suppressed by the crystal layer formed between the charge blocking layer and the upper electrode. In Example 7, distortion attributable to the stress of the upper electrode can be suppressed by the crystal layer formed between the photoelectric conversion layer and the upper electrode. This effect is obtained because each of chemical formulae 4, 5 and 6 constituting the crystal layer functions as a stress relieving layer capable of relieving the stress of the upper electrode. More specifically, ITO constituting the upper electrode has a tensile stress, whereas each of chemical formulae 4, 5 and 6 constituting the crystal layer has a compressive stress acting in the opposite direction on the tensile stress, and therefore, the tensile stress inherent in ITO is partially or entirely canceled by the compressive stress inherent in the material of the crystal layer. As a result, in Examples 1 to 6, good adherence is kept between the upper electrode and the organic material layer including a charge blocking layer and a crystal layer, and this provides an effect that distortion of the photoelectric conversion layer due to a stress of ITO can be reduced and in turn, deterioration of the photoelectric conversion efficiency can be suppressed. In Example 7, good adherence is kept between the upper electrode and the organic material layer including a crystal layer having a charge blocking function, and this provides an effect that distortion of the photoelectric conversion layer due to a stress of ITO can be reduced and in turn, deterioration of the photoelectric conversion efficiency can be suppressed. These results enable it to increase the thickness of the upper electrode.

On the other hand, in photoelectric conversion elements of Comparative Examples 1, 2 and 3, the photoelectric conversion efficiency with respect to the electric field intensity was found to become small in comparison to Examples 1 to 7. This is considered to result because in photoelectric conversion elements of Comparative Examples 1, 2 and 3, the adherence between the upper electrode and the charge blocking layer is not improved as in Examples 1 to 7.

Furthermore, it was found that when the material of chemical formula 5 is used as the crystal layer, the dark current density with respect to the electric field intensity can be greatly reduced.

In Examples above, those shown by chemical formulae 4 to 6 are used as the material of the crystal layer, but other materials can be used as long as it is a material capable of relieving the stress of the upper electrode.

In the context of the present invention, the following matters are disclosed.

(1) A photoelectric conversion element comprising in the following order, a substrate, a lower electrode, a photoelectric conversion layer and an upper electrode containing a transparent electrode material, wherein a stress relieving layer comprising a crystal layer capable of relieving a stress of the transparent electrode material is provided between the upper electrode and the photoelectric conversion layer.

(2) The photoelectric conversion element as described in (1) above, wherein

the transparent electrode material has a compressive stress and the crystal layer has a tensile stress.

(3) The photoelectric conversion element as described in (1) or (2) above, wherein

a charge blocking layer capable of inhibiting injection of a carrier into the photoelectric conversion layer is provided between the upper electrode and the photoelectric conversion layer, and

the crystal layer constitutes a part of the charge blocking layer.

(4) The photoelectric conversion element as described in any one of (1) to (3) above, wherein

the thickness of the crystal layer is from 20 to 50 nm.

(5) The photoelectric conversion element as described in any one of (1) to (4) above, wherein

the transparent electrode material contains an oxide.

(6) The photoelectric conversion element as described in any one of (1) to (5) above, wherein

the photoelectric conversion layer contains an amorphous layer.

(7) The photoelectric conversion element as described in any one of (1) to (6) above, wherein

the photoelectric conversion layer contains an organic material.

(8) An imaging device equipped with the photoelectric conversion element described in any one of (1) to (7) above, the imaging device comprising:

a semiconductor substrate having stacked thereabove the photoelectric conversion layer,

an electric charge accumulating part formed inside of the semiconductor substrate for accumulating an electric charge generated in the photoelectric conversion layer, and

a connection part for transmitting an electric charge of the photoelectric conversion layer to the electric charge accumulating part.

An imaging device equipped with the above-described photoelectric conversion element can be applied to an imaging device including a digital camera and a digital video camera, and an imaging device incorporated into a cellular phone and the like.

What is claimed is:

1. A photoelectric conversion element comprising, in the following order:
a substrate;
a lower electrode;
a photoelectric conversion layer; and
an upper electrode comprising a transparent electrode material,
wherein the photoelectric conversion element further comprises a stress relieving layer provided between the upper electrode and the photoelectric conversion layer, the stress relieving layer comprising a crystal layer capable of relieving a stress of the transparent electrode material.

2. The photoelectric conversion element as claimed in claim 1, wherein the transparent electrode material has a compressive stress and the crystal layer has a tensile stress.

3. The photoelectric conversion element as claimed in claim 1, which further comprises a charge blocking layer provided between the upper electrode and the photoelectric conversion layer, the charge blocking layer being capable of inhibiting injection of a carrier into the photoelectric conversion layer is,
wherein the crystal layer constitutes a part of the charge blocking layer.

4. The photoelectric conversion element as claimed in claim 2, which further comprises a charge blocking layer provided between the upper electrode and the photoelectric conversion layer, the charge blocking layer being capable of inhibiting injection of a carrier into the photoelectric conversion layer is,
wherein the crystal layer constitutes a part of the charge blocking layer.

5. The photoelectric conversion element as claimed in claim 1, wherein the crystal layer has a thickness of from 20 to 50 nm.

6. The photoelectric conversion element as claimed in claim 2, wherein the crystal layer has a thickness of from 20 to 50 nm.

7. The photoelectric conversion element as claimed in claim 3, wherein the crystal layer has a thickness of from 20 to 50 nm.

8. The photoelectric conversion element as claimed in claim 4, wherein the crystal layer has a thickness of from 20 to 50 nm.

9. The photoelectric conversion element as claimed in claim 1, wherein the transparent electrode material comprises an oxide.

10. The photoelectric conversion element as claimed in claim 2, wherein the transparent electrode material comprises an oxide.

11. The photoelectric conversion element as claimed in claim 3, wherein the transparent electrode material comprises an oxide.

12. The photoelectric conversion element as claimed in claim 4, wherein the transparent electrode material comprises an oxide.

13. The photoelectric conversion element as claimed in claim 1, wherein the photoelectric conversion layer comprises an amorphous layer.

14. The photoelectric conversion element as claimed in claim 2, wherein the photoelectric conversion layer comprises an amorphous layer.

15. The photoelectric conversion element as claimed in claim 3, wherein the photoelectric conversion layer comprises an amorphous layer.

16. The photoelectric conversion element as claimed in claim 4, wherein the photoelectric conversion layer comprises an amorphous layer.

17. The photoelectric conversion element as claimed in claim 1, wherein the photoelectric conversion layer comprises an organic material.

18. The photoelectric conversion element as claimed in claim 2, wherein the photoelectric conversion layer comprises an organic material.

19. The photoelectric conversion element as claimed in claim 3, wherein the photoelectric conversion layer comprises an organic material.

20. An imaging device comprising the photoelectric conversion element claimed in claim 1, the imaging device further comprising:
a semiconductor substrate,
an electric charge accumulating part formed inside of the semiconductor substrate for accumulating an electric charge generated in the photoelectric conversion layer, and
a connection part for transmitting an electric charge of the photoelectric conversion layer to the electric charge accumulating part.
